(19) United States
(12) Patent Application Publication
(10) Pub. No.: US 2026/0157001 A1
(43) Pub. Date: Jun. 4, 2026

(54) DISPLAY PANEL, ELECTRONIC DEVICE, AND REPAIRING METHOD FOR DISPLAY PANEL

(71) Applicant: CHENGDU VISTAR OPTOELECTRONICS CO., LTD., Chengdu (CN)

(72) Inventors: Shan GAO, Chengdu (CN); Xiuqi HUANG, Chengdu (CN); Xuan CAO, Chengdu (CN); Shangjun XU, Chengdu (CN); Wenqian LI, Chengdu (CN)

(73) Assignee: CHENGDU VISTAR OPTOELECTRONICS CO., LTD., Chengdu (CN)

(21) Appl. No.: 19/457,857

(22) Filed: Jan. 23, 2026

Related U.S. Application Data
(63) Continuation of application No. PCT/CN2024/107104, filed on Jul. 23, 2024.

(30) Foreign Application Priority Data
Aug. 7, 2023 (CN) 202310993733.9

(51) Int. Cl. H10H 29/49; H10H 29/01; H10H 29/24

(52) U.S. Cl. CPC H10H 29/49; H10H 29/012; H10H 29/24

(57) ABSTRACT

A display panel, an electronic device, and a repair method for the display panel. The display panel includes: a substrate; a first electrode group arranged in a first electrode area and including: a first power supply electrode, a second power supply electrode, and multiple data signal electrodes; and a binding pin group arranged in a binding region and including: a first bonding pin, a second bonding pin, and multiple third bonding pins. The first bonding pin is electrically connected to the first power supply electrode, the second bonding pin is electrically connected to the second power supply electrode, and the multiple third bonding pins are electrically connected on to the multiple data signal electrodes in a one-to-one correspondence.

### CROSS-REFERENCE TO RELATED APPLICATIONS

The present application is a continuation-application of International (PCT) Patent Application No. PCT/CN2024/107104, filed on Jul. 23, 2024, which claims priority to Chinese Patent Application No. 202310993733.9, filed on Aug. 7, 2023, the entire contents of which are incorporated herein by reference.

### TECHNICAL FIELD

The present disclosure relates to the field of display technologies, and in particular, to a display panel, an electronic device, and a repair method for a display panel.

### BACKGROUND

With the continuous development of display technologies, the application range of display panels has become increasingly widespread, and user requirements for display panels have also become higher, such as an increasing focus on display quality.

However, the inventors of the present disclosure have found that the display reliability of current display panels needs improvement, and the manufacturing difficulty needs to be further reduced.

### SUMMARY OF THE DISCLOSURE

A first technical solution provided in the present disclosure is providing a display panel. The display panel includes:
a substrate, having a first surface and a second surface that are opposite to each other; wherein the second surface is arranged with a first electrode area and at least one bonding area, and the first electrode area and the at least one bonding area are arranged at intervals along a first direction;
a first electrode group, disposed in the first electrode area and including a plurality of first electrodes arranged at intervals along a second direction; wherein the plurality of first electrodes include at least one first power electrode, at least one second power electrode, and a plurality of data signal electrodes; the second direction intersects the first direction; in the first electrode group, at least one of the following is satisfied: at least one of the at least one first power electrode is disposed between two of the plurality of data signal electrodes; and, at least one of the at least one second power electrode is disposed between two of the plurality of data signal electrodes; and
a bonding pin group, disposed in one of the at least one bonding area and including a plurality of bonding pins; wherein the plurality of bonding pins include at least one first bonding pin, at least one second bonding pin, and a plurality of third bonding pins; the at least one first bonding pin is electrically connected to the at least one first power electrode, the at least one second bonding pin is electrically connected to the at least one second power electrode, and the plurality of third bonding pins are electrically connected to the plurality of data signal electrodes in a one-to-one correspondence.

A second technical solution provided in the present disclosure is providing an electronic device, including the display panels as above, and the display panels are spliced together.

A third technical solution provided in the present disclosure is providing a repair method for a display panel. The method is applied to the display panel as above. The repair method includes:
in a case where a short circuit between a first target wiring of a plurality of first target wirings and a second target wiring is detected, determining a short point between the first target wiring and the second target wiring; and
performing a cutting process on the first target wiring on both sides of a short point;
wherein the plurality of first target wirings and the second target wiring are formed on the second surface of the substrate; each of at least part of the plurality of first target wirings and the second target wiring are arranged in different layers and have orthographic projections on the substrate that intersect; each of the plurality of first target wirings electrically connects a corresponding first power electrode and a corresponding first bonding pin or electrically connects a corresponding second power electrode and a corresponding second bonding pin.

### BRIEF DESCRIPTION OF THE DRAWINGS

FIG. 1 is a schematic diagram of the arrangement structure of light-emitting elements on a display panel in the related art.

FIG. 2 is a schematic diagram of a partial circuit structure for driving light-emitting elements to emit light in the related art.

FIG. 3 is a schematic front view of a display panel according to some embodiments of the present disclosure.

FIG. 4 is a schematic rear view of the display panel of FIG. 3.

FIG. 5 is a schematic diagram of a rear structure of a display panel in the related art.

FIG. 6 is a schematic diagram of the electrical connection structure between light-emitting elements and a second electrode group in the related art.

FIG. 7 is a schematic diagram of the structure of display panels spliced together in the related art.

FIG. 8 is a schematic diagram of the electrical connection structure between light-emitting elements and a second electrode group according to some embodiments of the present disclosure.

FIG. 9 is a schematic diagram of display panels spliced together according to some embodiments of the present disclosure.

FIG. 10 is a schematic diagram of a rear structure of a display panel according to other embodiments of the present disclosure.

FIG. 11 is a structural schematic diagram of a first electrode group according to some embodiments of the present disclosure.

FIG. 12 is a structural schematic diagram of an electronic device according to some embodiments of the present disclosure.

FIG. 13 is a cross-sectional structural diagram of the electronic device of FIG. 12 in an application scenario.

FIG. 14 is a top view schematic diagram of a rear side of the electronic device of FIG. 13.

FIG. 15 is a structural schematic diagram of a signal source according to some embodiments of the present disclosure.

FIG. 16 is a structural schematic diagram of a signal source according to other embodiments of the present disclosure.

FIG. 17 is a flowchart of a repair method for a display panel according to some embodiments of the present disclosure.

FIG. 18 is a schematic diagram of a rear structure of a display panel according to some embodiments of the present disclosure.

FIG. 19 is a schematic diagram of cutting processing performed on a first target wiring.

### DETAILED DESCRIPTION

The following clearly and completely describes the technical solutions in the embodiments of the present disclosure with reference to the accompanying drawings. Obviously, the described embodiments are only a part of the embodiments of the present disclosure, not all of them. Based on the embodiments of the present disclosure, all other embodiments obtained by those skilled in the art without making creative efforts shall fall within the scope of the present disclosure.

It should be noted that the terms “first”, “second”, etc. in the present disclosure are used for descriptive purposes only and cannot be understood as indicating or implying relative importance or implicitly indicating the quantity of the indicated technical features. Thus, features defined with “first” and “second” may explicitly or implicitly include at least one such feature. In the description of the present disclosure, “multiple” means at least two, such as two, three, etc., unless otherwise specifically defined. In addition, the terms “comprise”, “have”, and any variations thereof are intended to cover non-exclusive inclusion. For example, a process, method, system, product, or device that includes a series of steps or units is not limited to the listed steps or units, but may optionally further include steps or units not listed, or optionally include other steps or units inherent to these processes, methods, products, or devices.

Before introducing the solution of the present disclosure, a brief introduction to the background of the present disclosure is provided.

Currently, to achieve large-size displays, several display panels are spliced together. To achieve a bezel-less display panel and extremely small splicing gaps, the signal source for driving the display panel is conventionally bonded to the non-display surface of the display panel. There are currently two mainstream methods: the first is to use a single substrate (e.g., glass), with its front side used for display and the back side used for bonding the signal source; the second is to stack two substrates, where the surfaces of the two substrates facing away from each other are used as a display surface and for bonding the signal source, respectively.

As shown in FIG. 1, on the front side of the display panel, multiple light-emitting elements 11 (i.e., sub-pixels) form multiple display columns. The multiple light-emitting elements 11 in a same display column are electrically connected to a same data line 12, and light-emitting elements 11 in different display columns are electrically connected to different data lines 12. That is, the display columns correspond one-to-one with the data lines 12, and each data line 12 is electrically connected to all light-emitting elements 11 in a corresponding display column. The data line 12 is configured to transmit the data signal output by the signal source to the light-emitting elements 11 in the corresponding display column.

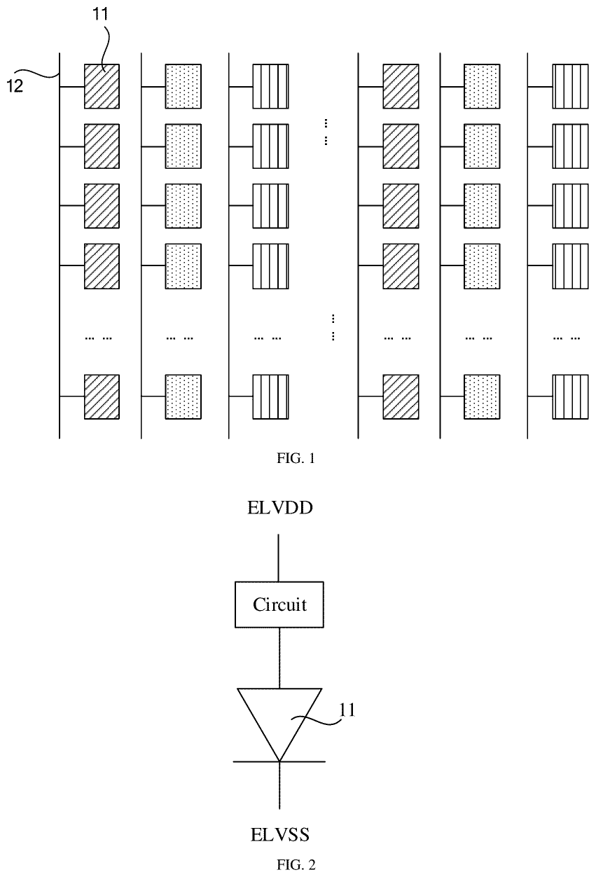

In addition to the data signal, for the light-emitting element 11 to emit light normally, as shown in FIG. 2, an ELVSS signal and an ELVDD signal are required to be applied to both ends of the light-emitting element 11, respectively. It should be noted that a certain circuit is connected in series between the light-emitting element 11 and the ELVDD signal, which is not described in the present disclosure.

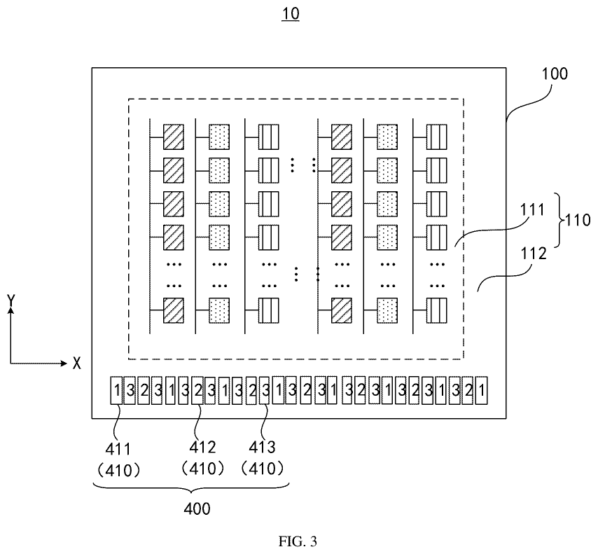

The solution of the present disclosure is described in detail below with reference to FIG. 3 to FIG. 19. It should be noted that for clarity of illustration, in the drawings, all electrodes and pins transmitting the first power signal are labeled “1”, all electrodes and pins transmitting the second power signal are labeled “2”, and all electrodes and pins transmitting the data signal are labeled “3”.

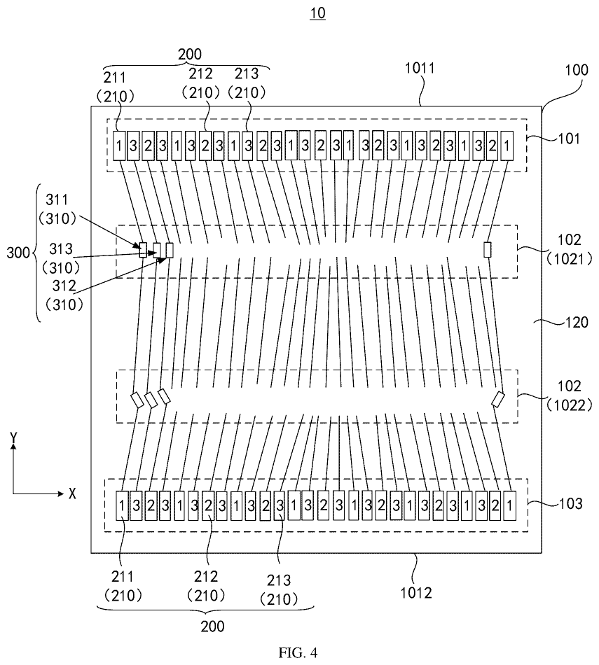

Referring to FIG. 3 and FIG. 4, in some embodiments of the present disclosure, the display panel 10 includes a substrate 100, a first electrode group 200, a bonding pin group 300, and a second electrode group 400.

The substrate 100 may be a flexible substrate or a rigid substrate, and its material may be glass, polyimide, plastic, etc. The substrate 100 may be a single-layer structure or a laminated structure formed by stacking multiple sub-substrates, which is not limited here. The substrate 100 has a first surface 110 and a second surface 120 that are opposite. The second surface 120 is configured for bonding a signal source. The first surface 110 includes a display area 111 and a non-display area 112. The display area 111 is arranged with structures such as light-emitting elements and data lines. The non-display area 112 is arranged with a second electrode group 400. The second electrode group 400 is configured to transmit signals from the signal source bonded on the second surface 120 to the light-emitting elements. For details, reference may be made to the description below.

The second surface 120 is arranged with a first electrode area 101 and a bonding area 102. The first electrode area 101 and the bonding area 102 are arranged at intervals along a first direction Y. The number of bonding areas 102 may be one, two, three, or more, which is not limited here. The drawings all illustrate the number of bonding areas 102 as two. The bonding area 102 is configured for bonding the signal source. It should be noted that when the number of bonding areas 102 is multiple, the multiple bonding areas 102 may all be configured for bonding the signal source, but it is only necessary to bond the signal source on at least one of the bonding areas 102 to enable normal display of the display panel 10. For details, reference may be made to the description below.

The first electrode group 200 is arranged in the first electrode area 101. The first electrode group 200 includes multiple first electrodes 210 arranged at intervals along a second direction X. The second direction X intersects with the first direction Y; they may be perpendicular or not. The multiple first electrodes 210 are insulated from each other. The multiple first electrodes 210 include at least one first power electrode 211, at least one second power electrode 212, and multiple data signal electrodes 213. The number of first power electrodes 211 may be one or multiple, and the number of second power electrodes 212 may be one or multiple. The first power electrode 211 is configured to transmit a first power signal. The second power electrode 212 is configured to transmit a second power signal. In one application scenario, the first power signal is an ELVDD signal, and the second power signal is an ELVSS signal. In another application scenario, the first power signal is an ELVSS signal, and the second power signal is an ELVDD signal. For ease of description, the following description assumes that the first power signal is the ELVDD signal and the second power signal is the ELVSS signal.

The data signal electrode 213 is configured to transmit a data signal. The data signal electrodes 213 correspond one-to-one with the multiple display columns on the first surface 110, and each data signal electrode 213 is simultaneously electrically connected to all light-emitting elements 11 in a corresponding display column.

Continuing to refer to FIG. 3, the second electrode group 400 includes multiple second electrodes 410 arranged at intervals along the second direction X. The multiple second electrodes 410 correspond one-to-one with the multiple first electrodes 210 in the first electrode group 200. Each second electrode 410 is electrically connected to a corresponding first electrode 210. The second electrode 410 is electrically connected to the corresponding first electrode 210 through a side wiring (not shown). It can be understood that the second electrode 410 electrically connected to the first power electrode 211 is configured to transmit the first power signal; the second electrode 410 electrically connected to the second power electrode 212 is configured to transmit the second power signal; the second electrode 410 electrically connected to the data signal electrode 213 is configured to transmit the data signal. For ease of description, the second electrode 410 connected to the first power electrode 211 is defined as a second electrode 411; the second electrode 410 connected to the second power electrode 212 is defined as a second electrode 412; the second electrode 410 connected to the data signal electrode 213 is defined as a second electrode 413.

The multiple second electrodes 413 in the second electrode group 400 correspond one-to-one with the display columns. That is, each second electrode 413 is simultaneously electrically connected to all light-emitting elements 11 in a corresponding display column to transmit data signals to the light-emitting elements 11 in the corresponding display column, respectively.

Continuing to refer to FIG. 3 and FIG. 4, in the embodiments, along the second direction X, the arrangement positions of the second electrodes 410 in the second electrode group 400 are the same as the arrangement positions of the first electrodes 210, that are electrically connected to these second electrodes 410, in the first electrode group 200.

Specifically, along the second direction X, when a certain second electrode 410 is an Electrode 1 in the second electrode group 400 (i.e., the first one among the electrodes in the second electrode group 400 when counting along second direction X; similar applies below), then along the second direction X, the first electrode 210 electrically connected to this second electrode 410 is also an Electrode 1 in the first electrode group 200, and so on. Along the second direction X, when a certain second electrode 410 is the last electrode in the second electrode group 400, then along the second direction X, the first electrode 210 electrically connected to this second electrode 410 is also the last electrode in the first electrode group 200.

This arrangement allows the side wirings electrically connecting the first electrode group 200 and the second electrode group 400 to be arranged in the same layer, avoiding short circuits caused by intersecting side wirings and reducing the difficulty of the preparation process.

Continuing to refer to FIG. 4, in the first electrode group 200, at least one first power electrode 211 is distributed between two data signal electrodes 213, and/or at least one second power electrode 212 is distributed between two data signal electrodes 213.

Specifically, only the first power electrode 211 may be distributed between two data signal electrodes 213, or only the second power electrode 212 may be distributed between two data signal electrodes 213, or both the first power electrode 211 and the second power electrode 212 may be distributed between two data signal electrodes 213.

Continuing to refer to FIG. 4, each bonding area 102 is arranged with a bonding pin group 300 for bonding the signal source (not shown). The bonding pin group 300 includes multiple bonding pins 310. The multiple bonding pins 310 include at least one first bonding pin 311, at least one second bonding pin 312, and multiple third bonding pins 313. The at least one first bonding pin 311 is electrically connected to the at least one first power electrode 211, the at least one second bonding pin 312 is electrically connected to the at least one second power electrode 212, and the multiple third bonding pins 313 correspond one-to-one with the multiple data signal electrodes 213. Each third bonding pin 313 is electrically connected to a corresponding data signal electrode 213.

Specifically, the number of third bonding pins 313 included in the bonding pin group 300 is equal to the number of data signal electrodes 213 included in the first electrode group 200, the third bonding pins 313 included in the bonding pin group 300 correspond one-to-one with the data signal electrodes 213 included in the first electrode group 200, and a corresponding set of one third bonding pin 313 and one data signal electrode 213 are electrically connected.

It can be understood that after the signal source is bonded to the bonding area 102, the first power signal output by the signal source is transmitted to the first power electrode 211 through the first bonding pin 311, the second power signal output by the signal source is transmitted to the second power electrode 212 through the second bonding pin 312, and the data signal output by the signal source is transmitted to the data signal electrode 213 through the third bonding pin 313.

In addition, in the embodiments, when there are multiple bonding areas 102, in any two adjacent bonding areas 102, the at least one first bonding pin 311 in one boding area 102 is electrically connected to the at least one first bonding pin 311 in the other boding area 102, the at least one second bonding pin 312 in one boding area 102 is electrically connected to the at least one second bonding pin 312 in the other boding area 102, and each third bonding pin 313 in one boding area 102 is electrically connected to a corresponding third bonding pin 313 in the other boding area 102, where the two third bonding pins 313 are electrically connected to a same data signal electrode 213.

Specifically, along the first direction Y, the first bonding pins 311 in the two adjacent bonding areas 102 are connected in series, the second bonding pins 312 in the two adjacent bonding areas 102 are connected in series, and the third bonding pins 313 electrically connected to the same data signal electrode 213 in the two adjacent bonding areas 102 are connected in series. This arrangement may ensure that bonding the signal source to any bonding area 102 can transmit the signal output by the signal source to the first surface 110 of the substrate 100.

Referring to FIG. 5, in the related art, multiple data signal electrodes 213 are arranged continuously, and no first power electrode 211 or second power electrode 212 exists between any two adjacent data signal electrodes 213. In this case, multiple second power electrodes 212 are distributed on both sides of the multiple data signal electrodes 213, and multiple first power electrodes 211 are distributed on both sides of the multiple second power electrodes 212, and there is only one bonding area 102, which brings the following problems.

First, multiple first power electrodes 211 and multiple second power electrodes 212 are gathered together, such that the areas where multiple first power electrodes 211 and multiple second power electrodes 212 are gathered (see the dashed box N in FIG. 5) have a high current density, which easily causes local temperature to be too high, resulting in abnormal display of the display panel 10.

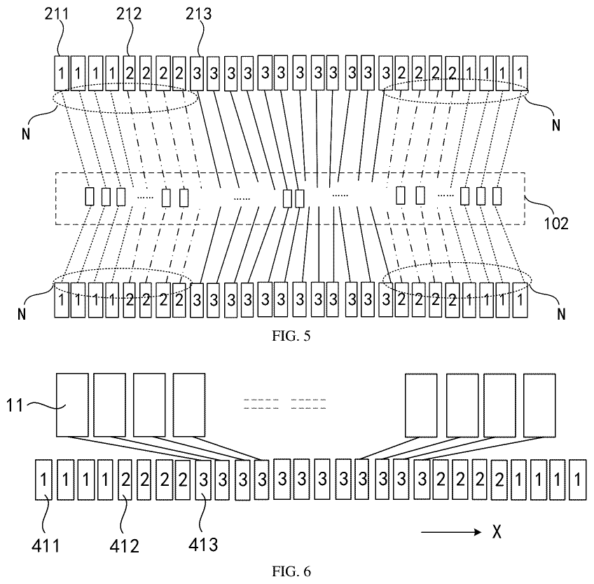

Second, when the arrangement position of the second electrode 410 in the second electrode group 400 is the same as the arrangement position of the electrically connected first electrode 210 in the first electrode group 200, as shown in FIG. 6, multiple second electrodes 413 are also gathered together, multiple second electrodes 412 are distributed on both sides of the multiple second electrodes 413, and multiple second electrodes 411 are distributed on both sides of the multiple second electrodes 412. In this case, along the second direction X, there is an IR drop problem, causing the brightness of the light-emitting elements 11 to change along the second direction X, resulting in uneven display.

Third, when the position of the second electrode 410 in the second electrode group 400 is the same as the position of the electrically connected first electrode 210 in the first electrode group 200, as shown in FIG. 6, multiple second electrodes 413 are also gathered together. Since each second electrode 413 needs to be electrically connected to the light-emitting elements in the corresponding display column through wiring, the slope of some wirings becomes smaller. In this case, to increase the slope of the wiring, the distance between the light-emitting element 11 and the second electrode 413 can only be increased, but this is not conducive to the bezel-less development of the display panel 10.

Fourth, referring to FIG. 7, when two display panels are spliced together to form a larger display panel, a support plate is needed to support each display panel simultaneously. To bond the signal source, a through slot is required to be opened on the support plate to expose the bonding area 102 on the display panel. To avoid affecting the strength of the support plate due to slotting, the bonding area 102 is first arranged close to the edge of the substrate 100. Further, when splicing the display panels, the substrates 100 are usually spliced head-to-head or tail-to-tail, that is, one of the substrates 100 is required to be rotated 180 degrees around the center point (head-to-head or tail-to-tail splicing can make the through slots opened on the support plate spaced a certain distance apart, ensuring the strength of the support plate). This brings a problem: when transferring the light-emitting elements 11 on the first surface 110 of the substrate 100, to meet the requirement that some substrates need to be rotated 180 degrees during splicing, two sets of transfer processes are required to be adopted, for example, one set is arranged according to RGB, and the other set is arranged according to BGR. Otherwise, the red light-emitting elements 11 will not be in a straight line after splicing, and the blue light-emitting elements 11 will not be in a straight line. The above consideration leads to increasing in the complexity of the process.

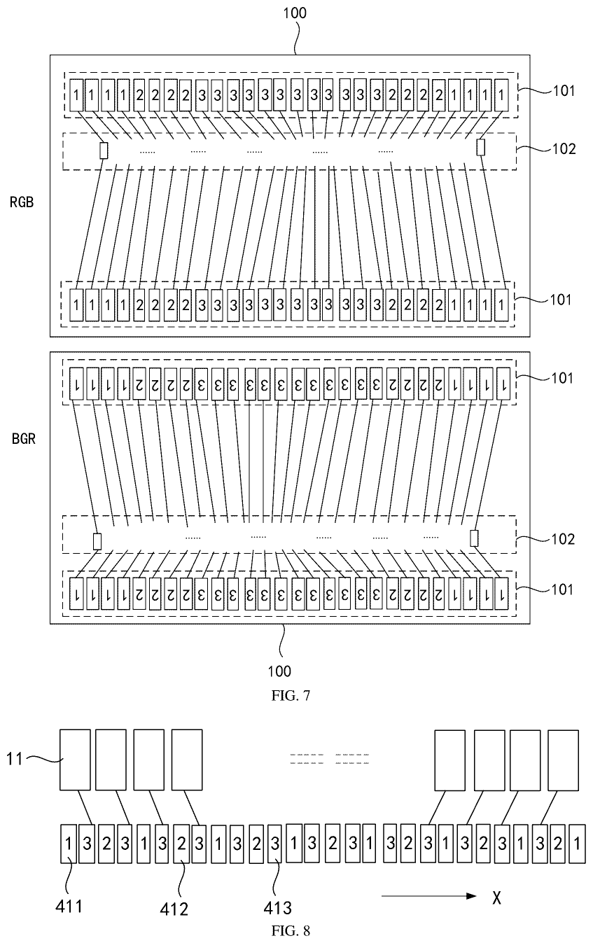

However, in the solution of the present disclosure, at least one first power electrode 211 is arranged between two data signal electrodes 213, and/or at least one second power electrode 212 is arranged between two data signal electrodes 213, thereby avoiding the gathering of first power electrodes 211 and/or avoiding the gathering of second power electrodes 212. On one hand, this may avoid high current density of the first power signal and/or the second power signal in the first electrode group 200, ensuring that there is no local high current density causing local temperature rise and other problems, thus avoiding abnormal display. On the other hand, when the arrangement position of the second electrode 410 in the second electrode group 400 is the same as the arrangement position of the electrically connected first electrode 210 in the first electrode group 200, at least one second electrode 411 and/or at least one second electrode 412 are also distributed between two second electrodes 413, thereby improving the uniformity of the first power signal and/or the second power signal in the second direction X, thus ensuring the uniformity of display brightness. In addition, as shown in FIG. 8, when the arrangement position of the second electrode 410 in the second electrode group 400 is the same as the arrangement position of the electrically connected first electrode 210 in the first electrode group 200, since at least one second electrode 411 and/or at least one second electrode 412 are also distributed between two second electrodes 413, the slope of the wirings electrically connecting the light-emitting elements 11 and the second electrode 413 and located at the edge becomes larger, thereby reducing the wiring space and facilitating the bezel-less development of the display panel 10.

In addition, when multiple bonding areas 102 are provided, the multiple bonding areas 102 can all be used for bonding the signal source, such that when splicing multiple display panels 10 together, it is not necessary to rotate the display panel 10 by 180 degrees. It is only necessary to select a suitable bonding area 102, such that when transferring the light-emitting elements 11, only one transfer process is needed. For ease of understanding, the structure of FIG. 9 is used as an example for illustration.

First, the two display panels 10 in FIG. 9 are defined as a first display panel 1 and a second display panel 2, respectively. When bonding the signal source, the bonding area 102 on the first display panel 1 farthest from the second display panel 2 can be selected to bond the signal source, and the bonding area 102 on the second display panel 2 farthest from the first display panel 1 can be configured to bond the signal source, thereby increasing the distance between the through slots opened on the support plate and ensuring the strength of the support plate without rotating the display panel 2 by 180 degrees.

It should be noted that although the above describes that setting multiple bonding areas 102 can increase the distance between the through slots opened on the support plate and ensure the strength of the support plate without rotating the display panel 2 by 180 degrees, this does not mean that the number of bonding areas 102 in the solution of the present disclosure must be multiple. That is, in some embodiments of the present disclosure, the number of the bonding area 102 may be one. In this case, the setting of the first electrode group 200 may avoid high current density of the first power signal and/or the second power signal in the first electrode group 200, ensuring that there is no local high current density causing local temperature rise and other problems, thus avoiding abnormal display.

Referring to FIG. 4, in some embodiments, the number of bonding areas 102 is two. For ease of description, the two bonding areas 102 are defined as a first bonding area 1021 and a second bonding area 1022. The distance from the first bonding area 1021 to a first side edge 1011 of the substrate 100 is equal to the distance from the second bonding area 1022 to a second side edge 1012 of the substrate 100. This setting may ensure the uniform distribution of the bonding areas 102.

Of course, in other embodiments, the distance from the first bonding area 1021 to the first side edge 1011 of the substrate 100 may be not equal to the distance from the second bonding area 1022 to the second side edge 1012 of the substrate 100.

Furthermore, in other embodiments, when the number of bonding areas 102 is three or more, along the first direction Y, the multiple bonding areas 102 may be uniformly distributed on the substrate 100, and the distance between any two bonding areas 102 is equal.

Continuing to refer to FIG. 4, in some embodiments, along the second direction X, the arrangement positions of the bonding pins 310 in the bonding pin group 300 are the same as the arrangement positions of the first electrodes 210 electrically connected to these bonding pins 310 in the first electrode group 200. That is, along the second direction X, when a first electrode 210 is an Electrode 1 in the first electrode group 200, then along the second direction X, the bonding pin 310 electrically connected to this first electrode 210 is also a Pin 1 in the bonding pin group 300, and so on. That is, the first electrodes 210 in the first electrode group 200 and the bonding pins 310 in the bonding pin group 300 are electrically connected one-to-one, and the arrangement order is the same. This setting may ensure that all wirings electrically connecting the first electrode group 200 and the bonding pin group 300 may be prepared using the same layer of metal, thereby reducing the preparation difficulty and preparation cost. That is, the orthographic projections of all wirings electrically connecting the first electrode group 200 and the bonding pin group 300 on the substrate 100 do not cross.

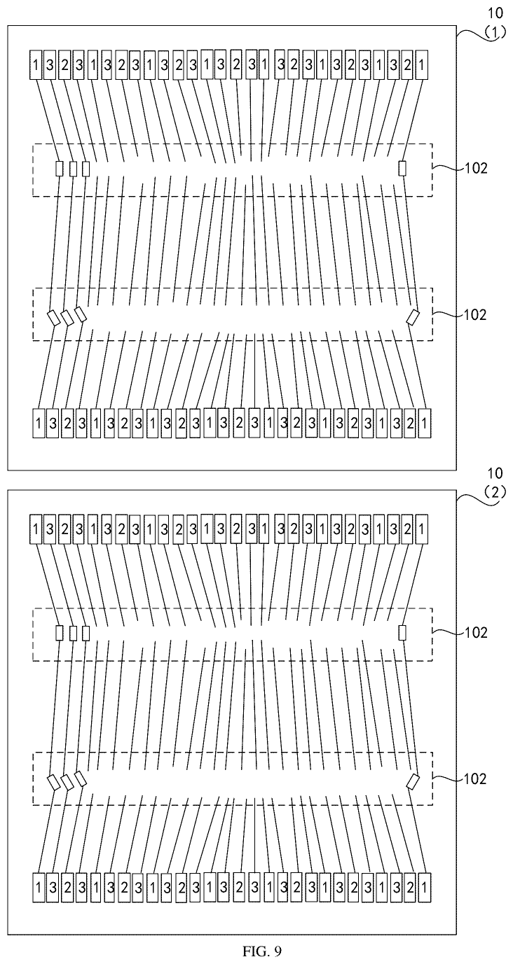

Referring to FIG. 10, in other embodiments, the number of first bonding pins 311 and the number of second bonding pins 312 are both multiple. Multiple second bonding pins 312 are distributed on both sides of the multiple third bonding pins 313, and multiple first bonding pins 311 are distributed on both sides of the multiple second bonding pins 312. Different from the embodiments in FIG. 4, in the instant embodiments, in all wirings electrically connecting the first electrode group 200 and the bonding pin group 300, the orthographic projections of some wirings on the substrate 100 intersect. Therefore, at least two layers of metal are needed to prepare all wirings electrically connecting the first electrode group 200 and the bonding pin group 300.

In summary, the present disclosure does not specifically limit the arrangement positions of the bonding pins 310 in the bonding pin group 300.

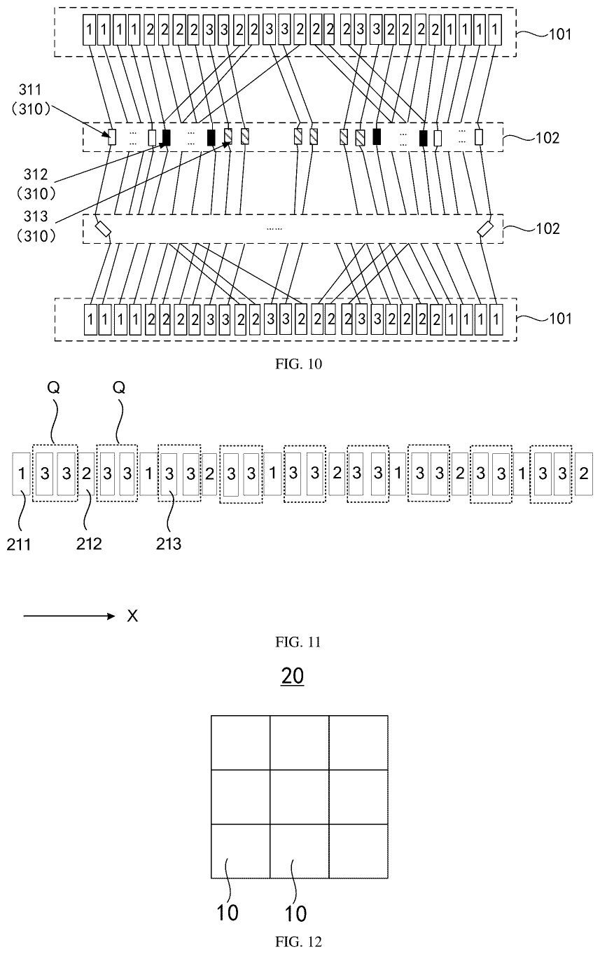

Referring to FIG. 11, when the number of first power electrodes 211 and the number of second power electrodes 212 are both multiple, the multiple data signal electrodes 213 are divided into multiple data signal electrode groups Q. Among them, one second power electrode 212 is distributed between some adjacent data signal electrode groups Q, and one first power electrode 211 is distributed between another part of adjacent data signal electrode groups Q.

Specifically, considering that the number of data signal electrodes 213 is greater than the number of first power electrodes 211 and the number of second power electrodes 212, grouping the multiple data signal electrodes 213 may ensure the uniformity of the distribution of the first power electrodes 211 and second power electrodes 212 among the multiple data signal electrodes 213.

Continuing to refer to FIG. 11, along the second direction X, the first power electrodes 211 and the second power electrodes 212 are alternately arranged. To put it simply, if only the first power electrodes 211 and the second power electrodes 212 are considered, the first power electrodes 211 and the second power electrodes 212 are alternately arranged (i.e., in an order of one first power electrodes 211, one second power electrode 212, one first power electrodes 211, one second power electrode 212, etc.). This setting may ensure the display uniformity of the display panel 10 in the second direction X and avoid the IR drop problem in the second direction X.

Of course, in other embodiments, along the second direction X, the first power electrodes 211 and the second power electrodes 212 may not be alternately arranged.

Continuing to refer to FIG. 11, to further ensure the uniformity of distribution, a second power electrode 212 and a first power electrode 211 are respectively distributed on both sides of any data signal electrode group Q.

Each data signal electrode group Q includes one or more data signal electrodes 213, and the number of data signal electrodes 213 included in each data signal electrode group Q may be different. For example, in FIG. 11, the data signal electrode group Q includes two data signal electrodes 213, while in FIG. 4, the data signal electrode group Q includes one data signal electrode 213. It is possible that some data signal electrode groups Q include one data signal electrode 213, and some data signal electrode groups Q include two or more data signal electrodes 213.

Continuing to refer to FIG. 10, when the number of the first power electrodes 211 and the number of the second power electrodes 212 are both multiple, in the first electrode area 101, some of the second power electrodes 212 are distributed among the multiple data signal electrodes 213, and another part of the second power electrodes 212 are each distributed on both sides of the multiple data signal electrodes 213. In addition, the multiple first power electrodes 211 are distributed on both sides of the multiple data signal electrodes 213 and the multiple second power electrodes 212.

Specifically, different from FIG. 4 and FIG. 11, in FIG. 10, only some of the second power electrodes 212 are distributed among the multiple data signal electrodes 213, while another part of the second power electrodes 212 are distributed on both sides of the multiple data signal electrodes 213. Furthermore, the multiple first power electrodes 211 are distributed on both sides of all the second power electrodes 212 and the data signal electrodes 213.

In other embodiments, only some of the first power electrodes 211 may be distributed among the multiple data signal electrodes 213. In summary, the present disclosure imposes no specific restrictions on the arrangement of the first electrodes 210 in the first electrode group 200.

Continuing to refer to FIG. 4, the second surface 120 is further arranged with a second electrode area 103. The first electrode area 101, the bonding area 102, and the second electrode area 103 are arranged sequentially at intervals along the first direction Y. The second electrode area 103 is also arranged with a first electrode group 200. The at least one first power electrode 211 in the second electrode area 103 is electrically connected to the at least one first bonding pin 311 in an adjacent bonding area 102. The at least one second power electrode 212 in the second electrode area 103 is electrically connected to the at least one second bonding pin 312 in the adjacent bonding area 102. The multiple data signal electrodes 213 in the second electrode area 103 are electrically connected one-to-one with the multiple third bonding pins 313 in the adjacent bonding area 102.

Specifically, the first electrode group 200 in the second electrode area 103 has an identical arrangement to the first electrode group 200 in the first electrode area 101. Furthermore, the electrical connection relationship between the first electrode group 200 in the second electrode area 103 and the bonding pin group 300 in the adjacent bonding area 102 is identical to the electrical connection relationship between the first electrode group 200 in the first electrode area 101 and the bonding pin group 300 in the adjacent bonding area 102.

The provision of the second electrode area 103 enables signals transmitted from the signal source to reach the second surface 120 simultaneously from both the first side edge 1011 and the second side edge 1012 of the substrate 100, ensuring transmission stability. It should be noted that in other embodiments, the second electrode area 103 may not be provided.

Continuing to refer to FIG. 4 and FIG. 10, the first bonding pins 311 in any two adjacent bonding areas 102 are electrically connected one-to-one, and the second bonding pins 312 are electrically connected one-to-one. This arrangement may ensure the stability of transmitting the first power signal and the second power signal.

It should be noted that in other embodiments, the first bonding pin 311 in a bonding area 102 may be simultaneously electrically connected to multiple first bonding pins 311 in an adjacent bonding area 102, and/or the second bonding pin 312 in a bonding area 102 may be simultaneously electrically connected to multiple second bonding pins 312 in an adjacent bonding area 102.

Referring to FIG. 12, in some embodiments of the present disclosure, an electronic device 20 is provided, including the display panel 10 described in any of the foregoing embodiments.

The electronic device 20 may be any type of device, such as a mobile phone, computer, or calculator, which is not limited herein.

The number of display panels 10 included in the electronic device 20 is multiple, and the multiple display panels 10 are spliced together.

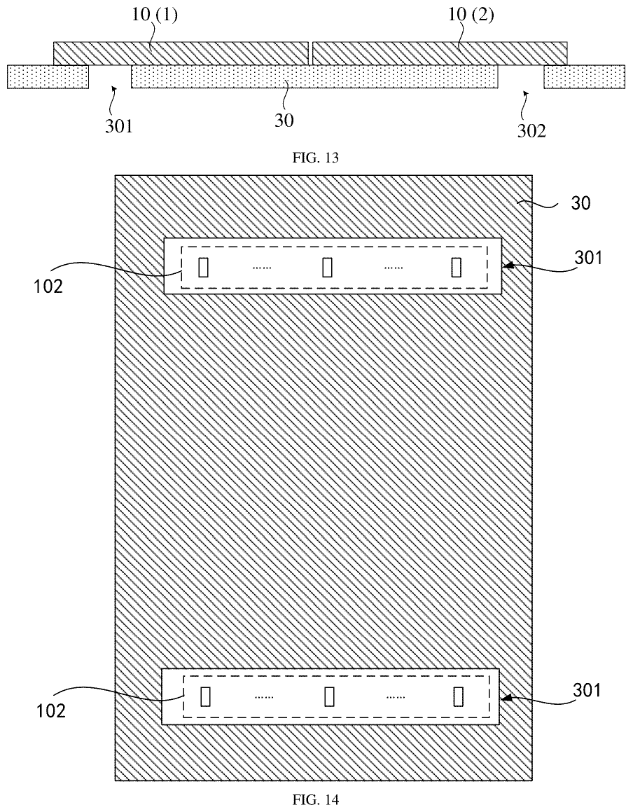

Referring to FIG. 13, the electronic device 20 further includes a support plate 30. The support plate 30 supports the multiple display panels 10 and is located on a non-display surface side of the display panels 10, i.e., the second surfaces 120 of the substrates 100 all face the support plate 30.

For ease of description, one of the multiple display panels 10 is defined as a first display panel 1, and another display panel 10 is defined as a second display panel 2. The first display panel 1 and the second display panel 2 are spliced together.

With reference to FIG. 13 and FIG. 14, the support plate 30 defines a first through slot 301 and a second through slot 302. The first through slot 301 exposes the bonding area 102 on the first display panel 1, and the second through slot 302 exposes the bonding area 102 on the second display panel 2.

A signal source (not shown) is bonded to the bonding area 102 exposed via the support plate 30. Specifically, a signal source is bonded to each display panel 10 to ensure normal display of the display panel 10.

To ensure the support strength of the support plate 30, other bonding areas 102 are distributed between the bonding area 102 exposed via the first through slot 301 and the bonding area 102 exposed via the second through slot 302. With reference to FIG. 9, this means that when bonding the signal source, the bonding area 102 on the first display panel 1 farthest from the second display panel 2 is used for bonding the signal source, and the bonding area 102 on the second display panel 2 farthest from the first display panel 1 is used for bonding the signal source, thereby increasing the distance between the first through slot 301 and the second through slot 302 and ensuring the strength of the support plate 30.

It should be noted that in other embodiments, the support plate 30 may not define the first through slot 301 and the second through slot 302. In this case, during assembly, the signal source may be bonded to the display panel 10 first, and then the display panel 10 may be placed on the support plate 30.

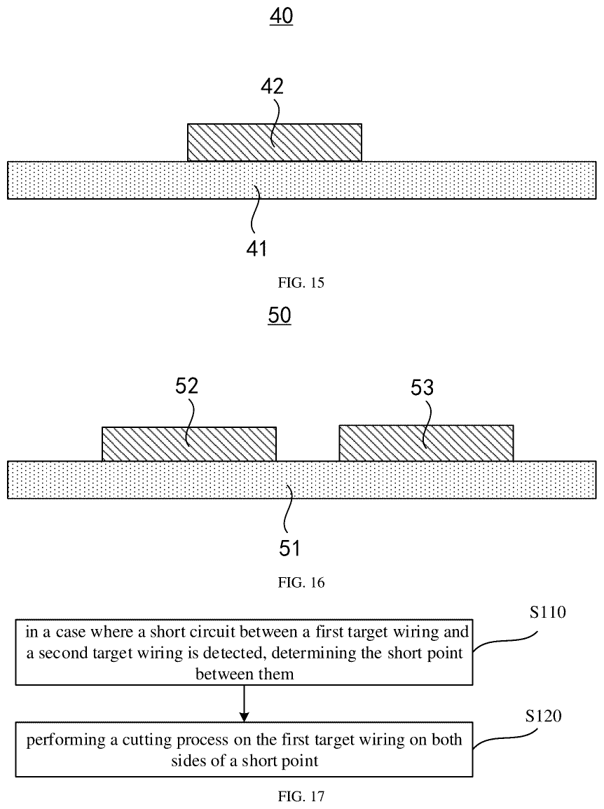

Referring to FIG. 4 and FIG. 15, in some embodiments of the present disclosure, a signal source 40 includes a substrate 41 and a drive chip 42 disposed on the substrate 41. Multiple pins of the drive chip 42 are electrically connected one-to-one with the multiple bonding pins 310 in the bonding pin group 300. That is, the drive chip 42 simultaneously outputs the first power signal, the second power signal, and the data signal. The material of the substrate 41 may be any material, which is not limited in the present disclosure.

Referring to FIG. 4 and FIG. 16, in other embodiments of the present disclosure, a signal source 50 includes a substrate 51, a first chip 52, and a second chip 53 disposed on the substrate 51.

Multiple pins of the first chip 52 are electrically connected one-to-one with the first bonding pins 311 and the second bonding pins 312 in the bonding pin group 300. Multiple pins of the second chip 53 are electrically connected one-to-one with the multiple third bonding pins 313 in the bonding pin group 300.

Specifically, the first chip 52 is bonded to the display panel 10 via the first bonding pins 311 and the second bonding pins 312, and the second chip 53 is bonded to the display panel 10 via the third bonding pins 313. That is, the first chip 52 transmits both the first power signal and the second power signal, while the second chip 53 only transmits the data signal.

In the embodiments shown in FIG. 16, the signal source 50 further includes a first wiring (not shown) and a second wiring (not shown) disposed on the substrate 51. The first chip 52 is electrically connected to the first bonding pins 311 and the second bonding pins 312 through multiple first wirings, respectively. The second chip 53 is electrically connected to the multiple third bonding pins 313 through multiple second wirings, respectively. The multiple first wirings are arranged in the same layer, and the multiple second wirings are arranged in the same layer, but the first wirings and the second wirings are not in the same layer.

Specifically, the first wirings achieve the electrical connection between the first chip 52 and the bonding pin group 300, and the second wirings achieve the electrical connection between the second chip 53 and the bonding pin group 300.

To flexibly adapt to various arrangements of the bonding pins 310 in the bonding pin group 300, all first wirings connected to the first chip 52 are arranged in the same layer, all second wirings connected to the second chip 53 are arranged in the same layer, but the first wirings and the second wirings are not in the same layer. That is, the signal source 50 requires at least two metal layers to form all the wirings.

A repair method for a display panel of the present disclosure is described below.

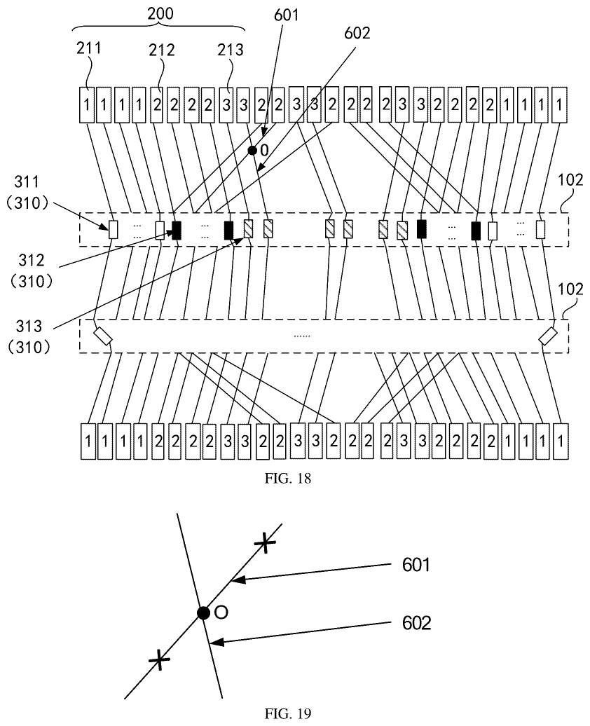

Referring to FIG. 17 and FIG. 18, when multiple second bonding pins 312 are distributed on both sides of multiple third bonding pins 313, and multiple first bonding pins 311 are distributed on both sides of the multiple second bonding pins 312, the repair method for the display panel includes the following operations.

At block S110: in a case where a short circuit between a first target wiring 601 and a second target wiring 602 is detected, determining the short point O between them.

At block S120: performing a cutting process on the first target wiring 601 on both sides of a short point O.

Specifically, both the first target wiring 601 and the second target wiring 602 are formed on the second surface 120 of the substrate 100. The number of first target wirings 601 is multiple, and at least part of the first target wirings 601 and the second target wiring 602 are arranged in different layers and their orthographic projections on the substrate 100 intersect. That is, at least part of the first target wirings 601 and the second target wiring 602 are made of different layers of metal. Consequently, during the manufacturing process, when environmental dust particles easily fall on the substrate 100, once external pressure is applied at the particle, a short circuit between different metal layers may occur, meaning there is a risk of short circuit between the first target wiring 601 and the second target wiring 602.

The first target wiring 601 is electrically connected to the first power electrode 211 and the first bonding pin 311, or the first target wiring 601 is electrically connected to the second power electrode 212 and the second bonding pin 312. The second target wiring 602 may be any wiring electrically connecting the first electrode group 200 and the bonding pin group 300.

Since the number of first target wirings 601 is multiple, removing one first target wiring 601 does not affect the normal display of the display panel 10. Therefore, when a short circuit between the first target wiring 601 and the second target wiring 602 is detected, the short point O is first located. After determining the short point O, as shown in FIG. 19, the first target wiring 601 is cut on both sides of the short point O. Consequently, the first target wiring 601 can no longer transmit signals to the first electrode group 200 or the bonding pin group 300, thus avoiding interference with the normal transmission of the second target wiring 602 and enabling the normal display of the display panel 10.

The above descriptions are only embodiments of the present disclosure and are not intended to limit the scope of the present disclosure. Any equivalent structural or process transformations made using the content of the specification and drawings of the present disclosure, or direct or indirect application in other related technical fields, shall likewise be included in the scope of the present disclosure.

1. A display panel, comprising:
a substrate, having a first surface and a second surface that are opposite to each other; wherein the second surface is arranged with a first electrode area and at least one bonding area, and the first electrode area and the at least one bonding area are arranged at intervals along a first direction;
a first electrode group, disposed in the first electrode area and comprising a plurality of first electrodes arranged at intervals along a second direction; wherein the plurality of first electrodes comprise at least one first power electrode, at least one second power electrode, and a plurality of data signal electrodes; the second direction intersects the first direction; in the first electrode group, at least one of the following is satisfied: at least one of the at least one first power electrode is disposed between two of the plurality of data signal electrodes; and, at least one of the at least one second power electrode is disposed between two of the plurality of data signal electrodes; and
a bonding pin group, disposed in one of the at least one bonding area and comprising a plurality of bonding pins; wherein the plurality of bonding pins comprise at least one first bonding pin, at least one second bonding pin, and a plurality of third bonding pins; the at least one first bonding pin is electrically connected to the at least one first power electrode, the at least one second bonding pin is electrically connected to the at least one second power electrode, and the plurality of third bonding pins are electrically connected to the plurality of data signal electrodes in a one-to-one correspondence.

2. The display panel according to claim 1, wherein an arrangement position of the plurality of bonding pins in the bonding pin group along the second direction is the same as an arrangement position of the plurality of first electrodes, that are electrically connected to the plurality of bonding pins, in the first electrode group along the second direction.

3. The display panel according to claim 1, wherein a number of the at least one first bonding pin and a number of the at least one second bonding pin are both plural; the at least one second bonding pin are distributed on both sides of the plurality of third bonding pins, and the at least one first bonding pin are distributed on both sides of the at least one second bonding pin.

4. The display panel according to claim 1, wherein a number of the at least one first power electrode in the first electrode group and a number of the at least one second power electrode in the first electrode group are both plural;
the plurality of data signal electrodes are divided into a plurality of data signal electrode groups; wherein for a part of adjacent data signal electrode groups among the plurality of data signal electrode groups, a corresponding one of the at least one second power electrode is disposed between each adjacent two data signal electrode groups in the part; for another part of adjacent data signal electrode groups among the plurality of data signal electrode groups, a corresponding one of the at least one first power electrode is disposed between each adjacent two data signal electrode groups in the other part.

5. The display panel according to claim 4, wherein the at least one first power electrode and the at least one second power electrode are alternately arranged along the second direction.

6. The display panel according to claim 5, wherein for each of plurality of data signal electrode groups, a corresponding second power electrode is arranged on a side of the data signal electrode group, and a corresponding first power electrode is arranged on another side of the data signal electrode group.

7. The display panel according to claim 4, wherein each of the plurality of data signal electrode groups comprises corresponding one or more of the plurality of data signal electrodes.

8. The display panel according to claim 1, wherein a number of the at least one first power electrode in the first electrode group and a number of the at least one second power electrode in the first electrode group are both plural;
in the first electrode area, a part of the at least one second power electrode is distributed among the plurality of data signal electrodes, another part of at least one second power electrode is distributed on both sides of the plurality of data signal electrodes, and the at least one first power electrode is distributed on both sides of the plurality of data signal electrodes and the plurality of second power electrodes.

9. The display panel according to claim 1, wherein the display panel further comprises:
a second electrode group, disposed on the first surface and comprising a plurality of second electrodes arranged at intervals along the second direction; wherein the plurality of second electrodes are electrically connected to the plurality of first electrodes in the first electrode group in a one-to-one correspondence;
wherein an arrangement position of the plurality of second electrodes in the second electrode group along the second direction is the same as an arrangement position of the plurality of first electrodes, that are electrically connected to the plurality of second electrodes, in the first electrode group along the second direction.

10. The display panel according to claim 1, wherein the second surface is further arranged with a second electrode area, and the first electrode area, the at least one bonding area, and the second electrode area are sequentially arranged at intervals along the first direction;
the second electrode area is arranged with another first electrode group that has a same configuration as the first electrode group in the first electrode area; the at least one first power electrode in the second electrode area is electrically connected to the at least one first bonding pin in an adjacent bonding area among the at least one bonding area; the at least one second power electrode in the second electrode area is electrically connected to the at least one second bonding pin in the adjacent bonding area; the plurality of data signal electrodes in the second electrode area are electrically connected to the plurality of third bonding pins in the adjacent bonding area in a one-to-one correspondence.

11. The display panel according to claim 1, wherein a number of the at least one bonding area is plural, and the first electrode area and the at least one bonding area are sequentially arranged at intervals along the first direction; each bonding area is arranged with the bonding pin group; for each adjacent two bonding areas, the at least one first bonding pin in one boding area is electrically connected to the at least one first bonding pin in the other boding area, the at least one second bonding pin in one boding area is electrically connected to the at least one second bonding pin in the other boding area, and each third bonding pin in one boding area is electrically connected to a corresponding third bonding pin in the other boding area, wherein the third bonding pin in one boding area and the corresponding third bonding pin in the other boding area are electrically connected to a same corresponding data signal electrode.

12. The display panel according to claim 11, wherein the at least one first bonding pin in one boding area is electrically connected to the at least one first bonding pin in the other boding area in a one-to-one correspondence, and the at least one second bonding pin in one boding area is electrically connected to the at least one second bonding pin in the other boding area in a one-to-one correspondence.

13. The display panel according to claim 11, wherein the number of the at least one bonding area is two, and the at least one bonding area comprise a first bonding area and a second bonding area; along the first direction, a distance from the first bonding area to a first side edge of the substrate is equal to a distance from the second bonding area to a second side edge of the substrate.

14. The display panel according to claim 1, wherein the at least one first power electrode is configured to transmit an ELVDD signal, and the at least one second power electrode is configured to transmit an ELVSS signal.

15. An electronic device, comprising a plurality of display panels that are spliced together; wherein each display panel comprises:
a substrate, having a first surface and a second surface that are opposite to each other; wherein the second surface is arranged with a first electrode area and at least one bonding area, and the first electrode area and the at least one bonding area are arranged at intervals along a first direction;
a first electrode group, disposed in the first electrode area and comprising a plurality of first electrodes arranged at intervals along a second direction; wherein the plurality of first electrodes comprise at least one first power electrode, at least one second power electrode, and a plurality of data signal electrodes; the second direction intersects the first direction; in the first electrode group, at least one of the following is satisfied: at least one of the at least one first power electrode is disposed between two of the plurality of data signal electrodes; and, at least one of the at least one second power electrode is disposed between two of the plurality of data signal electrodes; and
a bonding pin group, disposed in one of the at least one bonding area and comprising a plurality of bonding pins; wherein the plurality of bonding pins comprise at least one first bonding pin, at least one second bonding pin, and a plurality of third bonding pins; the at least one first bonding pin is electrically connected to the at least one first power electrode, the at least one second bonding pin is electrically connected to the at least one second power electrode, and the plurality of third bonding pins are electrically connected to the plurality of data signal electrodes in a one-to-one correspondence.

16. The electronic device according to claim 15, further comprising:
a support plate, supporting the plurality of display panels; wherein the second surfaces of the substrates of the plurality of display panels all face the support plate; and
a signal source, bonded to one of the at least one bonding area of each display panel.

17. The electronic device according to claim 16, wherein the signal source comprises a substrate and a drive chip disposed on the substrate, and a plurality of pins of the drive chip are electrically connected to the plurality of bonding pins in the bonding pin group in a one-to-one correspondence.

18. The electronic device according to claim 16, wherein the signal source comprises a substrate, a first chip disposed on the substrate, and a second chip disposed on the substrate; a plurality of pins of the first chip are electrically connected to the at least one first bonding pin and the at least one second bonding pin in the bonding pin group in a one-to-one correspondence; a plurality of pins of the second chip are electrically connected to the plurality of third bonding pins in the bonding pin group in a one-to-one correspondence.

19. The electronic device according to claim 18, wherein the signal source further comprises a plurality of first wirings and a plurality of second wirings disposed on the substrate; the first chip is electrically connected to the at least one first bonding pin and the at least one second bonding pin respectively via the plurality of first wirings; the second chip is electrically connected to the plurality of third bonding pins respectively via the plurality of second wirings; the plurality of first wirings are arranged in a same layer, the plurality of second wirings are arranged in another same layer, and the first wirings and the second wirings are arranged in different layers.

20. A repair method for a display panel, applied to a display panel; wherein the display panel comprises:
a substrate, having a first surface and a second surface that are opposite to each other; wherein the second surface is arranged with a first electrode area and at least one bonding area, and the first electrode area and the at least one bonding area are arranged at intervals along a first direction;
a first electrode group, disposed in the first electrode area and comprising a plurality of first electrodes arranged at intervals along a second direction; wherein the plurality of first electrodes comprise at least one first power electrode, at least one second power electrode, and a plurality of data signal electrodes; the second direction intersects the first direction; in the first electrode group, at least one of the following is satisfied: at least one of the at least one first power electrode is disposed between two of the plurality of data signal electrodes; and, at least one of the at least one second power electrode is disposed between two of the plurality of data signal electrodes; and
a bonding pin group, disposed in one of the at least one bonding area and comprising a plurality of bonding pins; wherein the plurality of bonding pins comprise at least one first bonding pin, at least one second bonding pin, and a plurality of third bonding pins; the at least one first bonding pin is electrically connected to the at least one first power electrode, the at least one second bonding pin is electrically connected to the at least one second power electrode, and the plurality of third bonding pins are electrically connected to the plurality of data signal electrodes in a one-to-one correspondence;
wherein the repair method comprises:
in a case where a short circuit between a first target wiring of a plurality of first target wirings and a second target wiring is detected, determining a short point between the first target wiring and the second target wiring; and
performing a cutting process on the first target wiring on both sides of a short point;
wherein the plurality of first target wirings and the second target wiring are formed on the second surface of the substrate; each of at least part of the plurality of first target wirings and the second target wiring are arranged in different layers and have orthographic projections on the substrate that intersect; each of the plurality of first target wirings electrically connects a corresponding first power electrode and a corresponding first bonding pin or electrically connects a corresponding second power electrode and a corresponding second bonding pin.
